(19) United States
(12) Patent Application Publication
(10) Pub. No.: US 2026/0002999 A1
(43) Pub. Date: Jan. 1, 2026

(54) SYSTEMS AND METHODS FOR ENERGY STORAGE SYSTEM STATE ESTIMATION AND MANAGEMENT

(71) Applicant: Impedyme Inc., Vienna, VA (US)

(72) Inventors: Ashkan Nazari, Vienna, VA (US); Arash Nazari, Vienna, VA (US); Angelos Stavrou, Vienna, VA (US)

(21) Appl. No.: 19/248,902

(22) Filed: Jun. 25, 2025

Related U.S. Application Data
(60) Provisional application No. 63/664,406, filed on Jun. 26, 2024.

(51) Int. Cl. G01R 31/367; G01R 31/374; G01R 31/3842; G01R 31/392; H01M 10/42

(52) U.S. Cl. CPC G01R 31/367; G01R 31/374; G01R 31/3842; G01R 31/392; H01M 10/4285

(57) ABSTRACT

Systems and methods for energy storage system (ESS) real-time state estimation and management. A system can include a deep learning (DL) module, which receives real-time measurement of time series data for current, voltage, and temperature of an ESS under test. The DL module can reshape the received time series data with a preprocessing component and then process the reshaped data with a DL component. The DL component can include various DL models such as DFFN, DCNN, LSTM, and ConLSTM, and utilize one or more of these DL models in estimating the SOH and/or remaining capacity for an ESS based on, for example, information about the ESS so as to generate more accurate estimations. The DL module can provide the estimations for the ESS under a variety of charging protocols. Such estimations can be utilized to control aspects of the ESS, such as optimizing its performance and extending its lifespan.

### CROSS-REFERENCE TO RELATED APPLICATION

This application claims priority under 35 U.S.C. § 119(e) to U.S. Provisional Application Ser. No. 63/664,406, title “SYSTEMS AND METHODS FOR ENERGY STORAGE SYSTEM STATE ESTIMATION AND MANAGEMENT,” filed on Jun. 26, 2024, which is herein incorporated by reference.

### FIELD

This application relates generally to energy storage systems, such as systems and methods for energy storage system state estimation and management.

### BACKGROUND

Rechargeable batteries have revolutionized numerous industries, particularly in transportation, by replacing conventional internal combustion engine vehicles with electric vehicles. These batteries, typically lithium-ion-based, are designed to be recharged multiple times, offering a sustainable and efficient power solution. In the context of electric vehicles, rechargeable batteries serve as the heart of the propulsion system, providing the necessary energy to drive the vehicle. The development of high-capacity and fast-charging batteries has significantly enhanced the viability of electric vehicles as a clean and viable alternative to traditional fossil fuel-powered vehicles. With advancements in battery technology and infrastructure, electric vehicles have emerged as a promising solution to address environmental concerns and reduce dependency on finite fossil fuels.

### SUMMARY

Aspects of the present disclosure relate to systems and methods for energy storage system state estimation and management.

Some embodiments relate to a method for evaluating an energy storage system (ESS). The method may comprise accessing, with a deep learning module, time series data of the ESS; reshaping, with the deep learning module, the received time series data of the ESS; and generating, with the deep learning module, predicted state information about the ESS based on the reshaped data.

Optionally, the time series data of the ESS comprise one or more of voltage time series data, current time series data, and temperature time series data.

Optionally, reshaping, with the deep learning module, the received time series data of the ESS comprises generating a partial session of the received time series data based on a predetermined cutoff voltage and/or a predetermined cutoff current.

Optionally, generating, with the deep learning module, the predicted information about the ESS based on the reshaped data comprises selecting one or more deep learning models of the deep learning module; and generating, with the selected one or more deep learning models of the deep learning module, the predicted state information about the ESS.

Optionally, the one or more selected deep learning models comprise one or more of deep feedforward neural network (DFFN), deep convolutional neural networks (DCNN), long short-term memory (LSTM), and convolutional LSTM (ConLSTM).

Optionally, the predicted state information about the ESS comprises predicted state of health (SOH) of the ESS under a plurality of charging protocols.

Optionally, the method further comprises providing the predicted state information about the ESS for controlling the ESS so as to optimize the ESS's performance and extend the ESS's lifespan.

Some embodiments relate to a system comprising at least one processor configured to perform one or more operations described herein.

Some embodiments relate to a non-transitory computer readable medium comprising program instructions that, when executed, cause at least one processor to perform one or more operations described herein.

These techniques may be used alone or in any suitable combination. The foregoing summary is provided by way of illustration and is not intended to be limiting.

### BRIEF DESCRIPTION OF DRAWINGS

The accompanying drawings may not be drawn to scale. In the drawings, each identical or nearly identical component that is illustrated in various figures is represented by a like numeral. For purposes of clarity, not every component may be labeled in every drawing. In the drawings:

FIG. 1 is a schematic diagram illustrating an exemplary system for energy storage system state estimation and management, according to some embodiments.

FIG. 2 is a block diagram illustrating an exemplary deep learning module of the exemplary system of FIG. 1, according to some embodiments.

FIG. 3A is a schematic diagram illustrating an exemplary feedforward neural network (FNN) with multiple hidden layers that may be implemented in the exemplary deep learning module of FIG. 2, according to some embodiments.

FIG. 3B is a schematic diagram illustrating an exemplary convolutional neural network (CNN) that may be implemented in the exemplary deep learning module of FIG. 2, according to some embodiments.

FIG. 3C is a schematic diagram illustrating an exemplary long short-term memory (LSTM) model that may be implemented in the exemplary deep learning module of FIG. 2, according to some embodiments.

FIG. 3D is a schematic diagram illustrating an exemplary convolutional LSTM (ConvLSTM) model that may be implemented in the exemplary deep learning module of FIG. 2, according to some embodiments.

FIG. 4 is a chart showing cell capacities with respect to cycle numbers and charging protocols, which may be provided by the exemplary system of FIG. 1, according to some embodiments.

FIGS. 5A-C are charts illustrating voltage, charging current, and cell temperature of nine observed cells over time with various charging protocols, respectively, which may be provided by the exemplary system of FIG. 1, according to some embodiments.

FIG. 6 is a table showing the specifications of the observed nine cells of FIGS. 5A-C at the beginning of life.

FIGS. 7A-I are charts illustrating estimated state of health (SOH) over cycle numbers with various charging protocols provided by the exemplary deep learning module of FIG. 2, according to some embodiments.

FIGS. 8A-I are charts illustrating absolute percentage error (APE) of the estimated SOH of FIGS. 7A-I, according to some embodiments.

FIGS. 9A-I are box plots of the APE of FIGS. 8A-I, according to some embodiments.

FIG. 10 is a chart comprising the mean absolute percentage error (MAPE) and the mean deviation from the MAPE (MSigma) between feedforward neural network (FNN), LSTM, ConvLSTM, and deep convolutional neural network (DCNN) models implemented in the exemplary deep learning module of FIG. 2, according to some embodiments.

FIGS. 11A-B are charts illustrating measured time to 80% state of charge (SOC) over cycle numbers for two different charging protocols, respectively, according to some embodiments.

FIG. 12 is a chart showing cycle life distribution of an exemplary training dataset including 124 cells.

FIG. 13 is a chart illustrating exemplary inputs into the exemplary deep learning module of FIG. 2, according to some embodiments.

FIGS. 14-25 are charts illustrating estimated state of health (SOH) over cycle numbers with various charging protocols provided by the exemplary deep learning module of FIG. 2, according to some embodiments.

### DETAILED DESCRIPTION

The inventors have recognized and appreciated techniques for accurately estimating the state of health (SOH) for energy storage systems (ESS) in real time, and/or predicting the state of safety (SOS) for the ESS (such as through anomaly detection). Techniques described herein can facilitate the transition to sustainable energy, such as in warranty analysis for electric vehicle (EV), and help manufacturers to build more durable EVs and reduce the maintenance cost.

The inventors have recognized and appreciated that conventional systems may provide inaccurate results. Conventional systems generally require extracting input features that are representative cell capacity such as cell charging time, sample entropy, initial cell temperature, charge voltage, and final charge current, and rely on the statistical-based features which has correlations with the cell cycle life. Such conventional systems may be only capable of predicting cell cycle life, but incapable of estimating remaining cell capacity through the cell lifespan, since inconsistency often exists between the input features representative cell capacity and the corresponding remaining capacity and/or SOH.

The inventors have recognized and appreciated systems and methods that can be used in a smart platform such as a cloud-based platform with corresponding mobile applications to allow users, such as residential user or industrial operator, to monitor their batteries. Techniques described herein can employ various machine learning models such as deep learning models to obtain battery SOH, which should be highly applicable for the EV and ESS applications under real-world operation. Integrating the smart platform in battery management systems (BMS) can enhance BMS functionality through the intelligent health prognostics systems offered by the smart platform.

According to aspects of the present disclosure, a system for ESS state estimation and management may include a deep learning module. The deep learning module may receive time series data for current, voltage, and temperature of an ESS under test, which can be measured in real time. The deep learning module may estimate the SOH and remaining capacity (e.g., duration of time or distance that a battery can continue to reliably and efficiently power a vehicle before it requires replacement or significant performance degradation) for the ESS under test under a variety of charging protocols. Such estimations can be utilized to control aspects of the ESS, such as optimizing its performance and extending its lifespan.

The deep learning module may include a preprocessing component and a deep learning component. Various deep learning models can be evaluated and integrated into a robust data-driven predictive component. For example, the deep learning component may include one or more deep learning models including, but not being limited to, deep feedforward neural network (DFFN), deep convolutional neural networks (DCNN), long short-term memory (LSTM), and convolutional LSTM (ConLSTM).

The preprocessing component may be configured to reshape the received time series data. For example, a selected portion of a charging session data, but not the entire session data, can be used to build the component. The deep learning component may receive the reshaped data and generate the estimations. One or more of the integrated deep learning models can be used based on, for example, information about the ESS under test (e.g., the charging session data) so as to generate more accurate estimations.

Techniques described herein requires no feature extraction from the raw charging/discharging data (such as charging/discharging time), which would require a lot of domain-specific experience. Rather, the deep learning module described herein can conduct the efficient feature extraction from the raw data (current, voltage, and temperature) directly. Techniques described herein enable accurate estimation of SOH for ESS, which may include accurately estimating the cell's remaining capacity at any point and obtaining variations in the cell capacity throughout a battery cell's lifespan.

In the following description, numerous specific details are set forth regarding the systems and methods of the disclosed subject matter and the environment in which such systems and methods may operate, etc., in order to provide a thorough understanding of the disclosed subject matter. In addition, it will be understood that the examples provided below are exemplary, and that it is contemplated that there are other systems and methods that are within the scope of the disclosed subject matter.

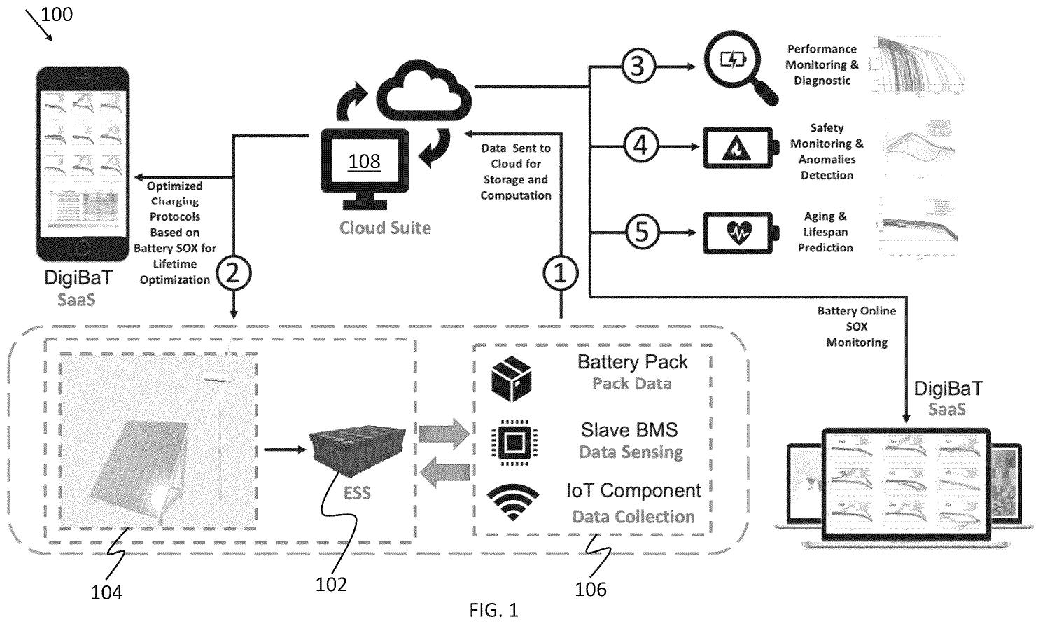

FIG. 1 shows an exemplary system 100 for energy storage system state estimation and management. The system 100 may include an energy storage system (ESS) 102, which may store energy provided by energy sources 104. For example, the ESS 102 may include packs of rechargeable battery cells. The ESS 102 may allow excess energy generated during times of low demand to be stored for later use when demand is high or when renewable energy sources like solar or wind are not producing electricity.

The ESS 102 may be in communication with a management system 106. The management system 106 may include battery management system (BMS) having sensors to measure field data 1 such as voltage, current, and temperature data, and the internet of things (IoT) components configured to provide the field data 1 to a cloud suite 108.

The cloud suite 108 may generate various output results based on the field data 1. The output results of the cloud suite 108 may include information 3 for performance monitoring & diagnostic, information 4 for safety monitoring & anomalies detection, and information 5 regarding aging & lifespan prediction. The cloud suite 108 may generate information 2 regarding optimized charging protocols based on the field data 1 and/or other outputs of the cloud suite 108 such as information 3-5, and provide the optimized charging protocols to the BMS for controlling aspects of the ESS 102 such as optimizing its performance and extending its lifespan.

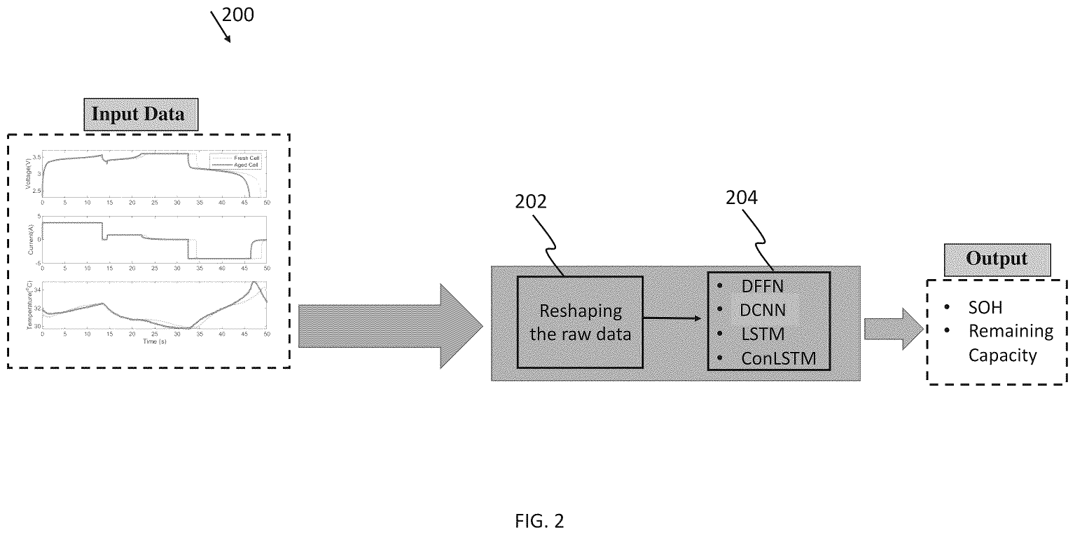

The cloud suite 108 may include a deep learning module (e.g., deep learning module 200 as shown in FIG. 2). The deep learning module may include multiple deep learning models. One or more of the deep learning models of the deep learning module may be used in generating the output results of the cloud suite 108.

The outputs of the cloud suite 108 may be accessed through a software (e.g., software as a service (SaaS)). The software may be referred to as digital battery twin (DigiBaT). The output results of the cloud suit 108 may be provided to DigiBaT for visualization.

FIG. 2 shows an exemplary deep learning module 200 of the system 100. The deep learning module 200 may receive field data such as measured time series data for current, voltage, and temperature of one or more battery cells and/or packs. The deep learning module 200 may provide estimations of aspects of the measured battery cells and/or packs including, for example, state of health (SOH) and remaining capacity (e.g., duration of time or distance that a battery can continue to reliably and efficiently power a vehicle before it requires replacement or significant performance degradation).

The deep learning module 200 may include a preprocessing component 202 and a deep learning component 204. The preprocessing component 202 may be configured to reshape the received field data. The deep learning component 204 may receive the reshaped field data and generate the estimations. The deep learning component 204 may include one or more deep learning models including, but not limited to, deep feedforward neural network (DFFN), deep convolutional neural networks (DCNN), long short-term memory (LSTM), convolutional LSTM (ConLSTM).

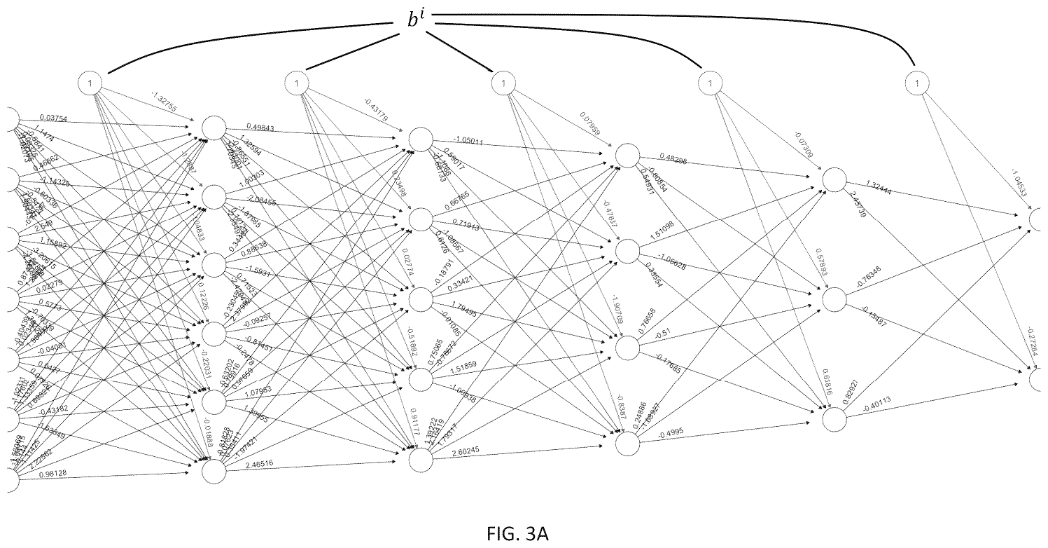

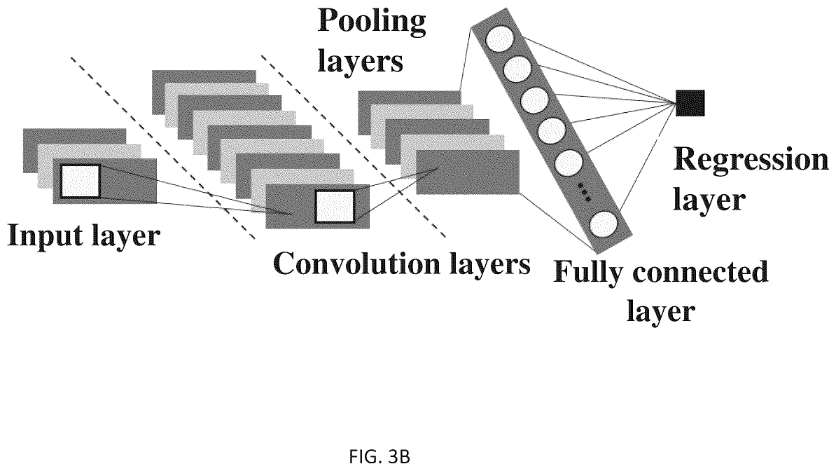

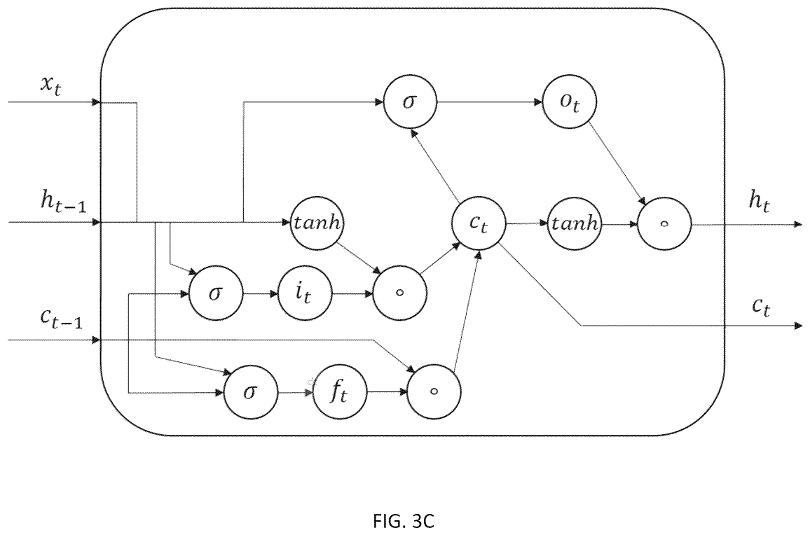

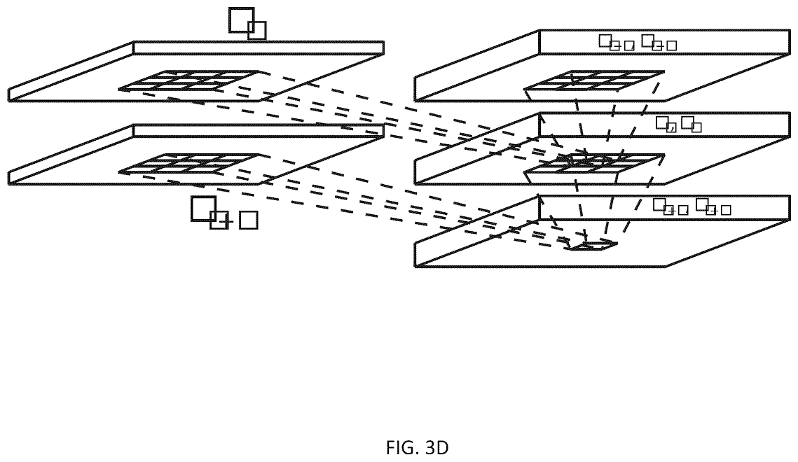

FIGS. 3A-3D show exemplary deep learning models that may be integrated in the deep learning component 204. FIG. 3A shows an exemplary feedforward neural network (FNN) with multiple hidden layers.

$${h}^{i + 1} ( {b}^{i} , {W}^{i} , {h}^{i} ) = f ( {b}^{i} + {W}^{i} {h}^{i} )$$

where hⁱ and hⁱ⁺¹ represent the activations of hidden layers i and i+1, respectively. Also Wⁱ represents the matrix of the weight in layer i, and bⁱ represents the bias vector (as marked in Error! Reference source not found.) in layer i. The activations hⁱ of the layer i can be calculated from the above Eq based on the activation hⁱ⁻¹ of the layer below. The activation function f can be implemented using various functions such as the Hyperbolic Tangent, Sigmoid, and Rectified Linear functions shown as follows:

$$tanh ( x ) = \frac{{e}^{x} - {e}^{- x}}{{e}^{x} + {e}^{- x}}$$

$$σ ( x ) = \frac{1}{1 + {e}^{- x}}$$

$$ReLu ( {x}_{i} ) = max ( {x}_{i} , 0 )$$

In order to train the model, a cost function (e.g., error) may be defined and the cost may be minimized using optimization procedures. Gradient descent may refer to a method of training the model in which backpropagation is utilized to obtain the gradients. If assuming the cost function as shown below, the gradient of the cost function can be calculated to obtain the weight matrix of the output layer through the following equations:

$$E ( x , \hat{y} , θ ) = \frac{1}{2} {‖ {f}_{θ} ( x ) - \hat{y} ‖}^{2}$$

$${h}_{j}^{i + 1} ( {b}_{j}^{i} , {W}_{j}^{i} , {h}^{i} ) = tanh ( {b}_{j}^{i} + {W}_{j}^{i} {h}^{i} )$$

$$\frac{\partial E}{\partial {W}_{ij}^{n - 1}} = \frac{\partial \frac{1}{2} {‖ {f}_{θ} ( x ) - \hat{y} ‖}^{2}}{\partial {W}_{ij}^{N - 1}} = ( {y}_{i} - {\hat{y}}_{i} ) \frac{\partial {f}_{θ} ( x )}{\partial {W}_{ij}^{N - 1}} = ( {y}_{i} - {\hat{y}}_{i} ) \frac{\partial {h}_{i}^{N}}{\partial {W}_{ij}^{N - 1}} = ( {y}_{i} - {\hat{y}}_{i} ) [ 1 - {tanh}^{2} ( {b}_{i}^{N - 1} + {W}_{i}^{N - 1} {h}^{N - 1} ) ] {h}_{j}^{N - 1}$$

$$\frac{\partial E}{\partial {W}_{ij}^{n - 1}} = {δ}_{i}^{n} \frac{\partial {h}_{i}^{n}}{\partial {W}_{ij}^{n - 1}}$$

$${∇}_{θ} {E}_{θ} ( x ) = \{ ( \frac{\partial E}{\partial {W}^{i}} , \frac{\partial E}{\partial {b}^{i}} ) \vert i = 0 ⋯ N - 1 \}$$

Using the method of gradient descent, the derivative of the cost function towards the parameters ∇_{θ}E_{θ}(x,ŷ) may be computed. Then the vector of the parameters in the space of θ showing the direction of increasing cost can be obtained. As a result, the cost can reduce through moving in the opposite direction. This method may have limitations as ∇_{θ}E_{θ}(x,ŷ) is a local measure and only provides the gradients for input X and parameters θ.

The parameters change as the input changes, which causes the gradient change. A solution for this issue is to select part of the input dataset through randomly sampling and conduct a small update to the parameters in the opposite direction of the gradient θ=θ−λ∇_{θ}E_{θ}(x,ŷ). In this approach, λₒ is the initial learning rate and we can adjust it to decrease over time.

$${λ}_{learning} ( n ) = {λ}_{o} \cdot {γ}^{n}$$

For instance, the learning rate can exponentially decay at the n'th iteration shown in the above Eq. Although the FNN is highly flexible and powerful to find the complexity of the relation between the input and output throughout its hidden layers, the computational load grows dramatically as the size of the input or the number of the hidden units increase.

FIG. 3B shows an exemplary convolutional neural network (CNN). In this approach, despite the neural networks that all the units from one layer get connected to all units in the next layer, the neurons connect only locally to neurons that correspond to the same neighborhood and representative of the parts from the same object. In CNN, instead of using matrix multiplication, convolutions will be used. The operation of 2-dimensional convolution is shown as follows:

$$S ( i , j ) = ( X * W ) ( i , j ) = {\sum }_{m} {\sum }_{n} X ( i - m , j - n ) W ( m , n )$$

where X is an input matrix and W is a kernel matrix used to build the CNN architecture. A typical structure for.

The illustrated CNN includes a convolution layer, a pooling layer and a fully connected layer. The convolution layer may extract features from the input data and send the extracted features to the activation function. A pooling layer (e.g., max pooling) may keep the maximum value for local groups of channels so as to avoid a huge number of channels sent to the activation function and therefore provide robust learning. The pooling layer may be configured to: i) pick a window size (e.g., 2 or 3); ii) pick a stride moving range of pixels (e.g., 2); iii) slide the window across the filtered input; and iv) for each window, the maximum value is taken. It should be appreciated that a CNN can include one or more convolution layers and/or one or more pooling layers, which may be toward shaping global features. The CNN may include a fully connected layer and a regression layer. In the fully connected layer, there is voting by the set of values to determine the output of the regression layer. The fully connected layer and the regression layer may be disposed as the last two layers of the CNN.

The inventors have recognized and appreciated that as the input to the deep learning module 200 involves time series data which has inputs that may be constantly changing, the deep learning component 204 should include deep learning models that can consider the time memory for the future prediction (e.g., LSTM, ConvLSTM). FIG. 3C Error! Reference source not found. shows an exemplary LSTM. The LSTM can receive input data and unroll the input data in time toward learning from each time step. For example, fₜ, iₜ, cₜ, oₜ, and hₜ may be calculated from the following equations:

$$\begin{matrix}{f}_{t} = σ ( {W}_{fc} ∘ {c}_{t + 1} + {W}_{fh} {h}_{t - 1} + {W}_{fx} {x}_{t} + {b}_{f} ) \\ {i}_{t} = σ ( {W}_{ic} ∘ {c}_{t - 1} + {W}_{ih} {h}_{t - 1} + {W}_{ix} {x}_{t} + {b}_{i} ) \\ {c}_{t} = {f}_{t} ∘ {c}_{t - 1} + {i}_{t} ∘ tanh ( {W}_{ch} {h}_{t - 1} + {W}_{cx} {x}_{t} + {b}_{c} ) \\ {o}_{t} = σ ( {W}_{oc} ∘ {c}_{t} + {W}_{oh} {h}_{t - 1} + {W}_{ox} {x}_{t} + {b}_{o} ) \\ {h}_{t} = {o}_{t} ∘ tanh ( {c}_{t} )\end{matrix}$$

where σ and tanh represent the sigmoid and hyperbolic tangent activation functions, respectively; w represents the different weight matrices; xₜ represents the input at the present timestep; hₜ and hₜ₋₁ represent the cell at current time step and the previous time step, respectively; and Cₜ₋₁ and Cₜ represent the cell's previous memory state and current memory state, respectively. The (∘) operator denotes the Hadamard product. Also, there are three gates: the input gate iₜ, the forget gate gₜ, and the output gate oₜ.

FIG. 3D shows an exemplary ConvLSTM. ConvLSTM has the capability to enhance the ability of LSTM to store the extracted information. The ConvLSTM may contain hidden state and cell state units. In contrast with LSTM where the input and hidden states are multiplied by the weights directly, in ConvLSTM, the convolution with the weights needs to be applied as follows:

$$\begin{matrix}{f}_{t} = σ ( {W}_{fc} ∘ {c}_{t + 1} + {W}_{fh} {h}_{t - 1} + {W}_{fx} {x}_{t} + {b}_{f} ) \\ {i}_{t} = σ ( {W}_{ic} ∘ {c}_{t - 1} + {W}_{ih} {h}_{t - 1} + {W}_{ix} {x}_{t} + {b}_{i} ) \\ {c}_{t} = {f}_{t} ∘ {c}_{t - 1} + {i}_{t} ∘ tanh ( {W}_{ch} {h}_{t - 1} + {W}_{cx} {x}_{t} + {b}_{c} ) \\ {o}_{t} = σ ( {W}_{oc} ∘ {c}_{t} + {W}_{oh} {h}_{t - 1} + {W}_{ox} {x}_{t} + {b}_{o} ) \\ {h}_{t} = {o}_{t} ∘ tanh ( {c}_{t} )\end{matrix}$$

The (∘) operator and (*) denote the Hadamard product and the convolution operator, respectively. It should be appreciated that when the size of the kernel is 1×1, the ConvLSTM becomes the same as the LSTM.

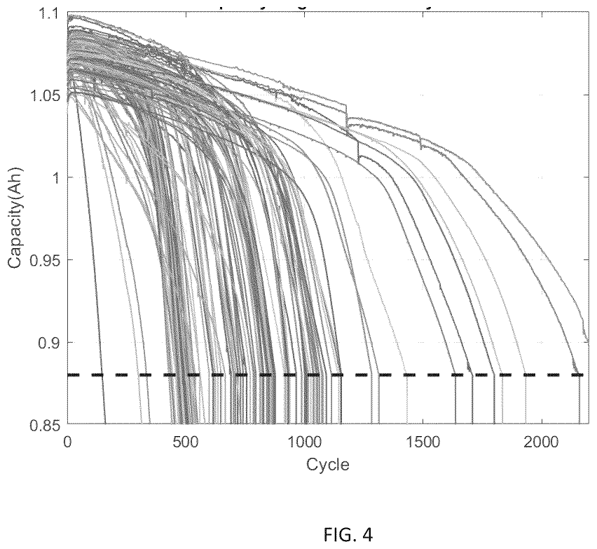

The output results of the cloud suite 108 may include the information 3 for performance monitoring & diagnostic. An example of the information 3 is shown in FIG. 4 as a chart illustrating the cell capacities with respect to the cycle numbers and charging protocols, which may be provided by the system 100. In the illustrated example, the fresh cells possess discharge capacity between 1.05 to 1.10 Ah; however, they will end up with different degradation paths. In the EV industry, 80% of the nominal fresh cell capacity is considered as the end of life (EOL). At the end of life, the cell degradation rate highly increases, and it reaches to the “elbow point” shown with a dash line in FIG. 4. It should also be appreciated that different cells may have different initial capacities. Generally, the cell manufacturing and formation process may cause fresh cell capacity to deviate from the nominal capacity defined by the cell manufacturer. In the illustrated example, a maximum deviation of 4.5% from the nominal capacity is observed for the 124 cells.

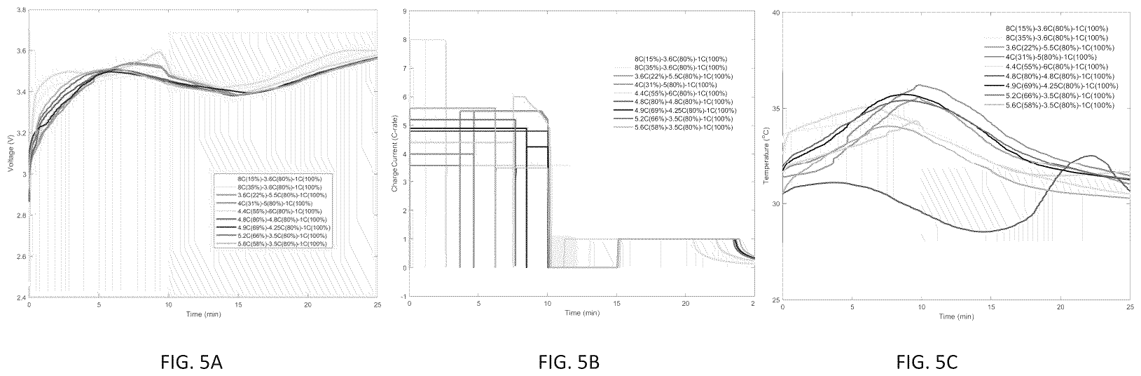

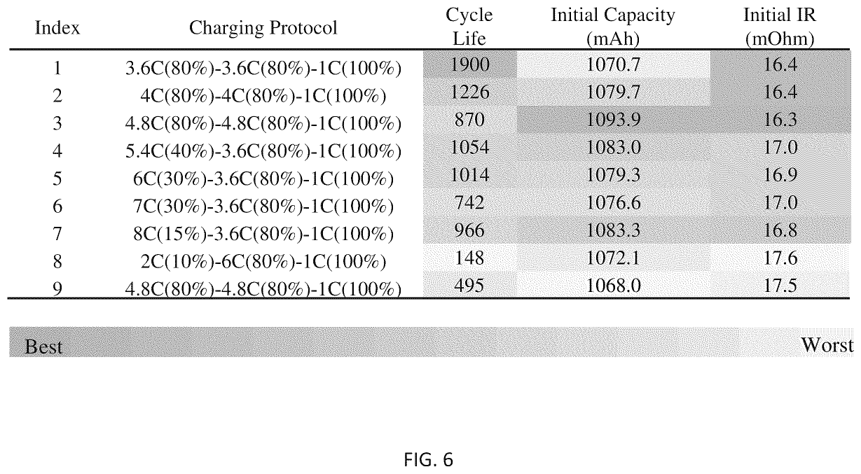

The output results of the cloud suite 108 may include the information 4 for safety monitoring & anomalies detection. An example of the information 4 is shown in FIGS. 5A-C as charts illustrating voltage, charging current, and cell temperature of nine observed cells over time with various charging protocols, respectively. FIG. 6 is a table showing the specifications of the observed nine cells of FIGS. 5A-C at the beginning of life. in order to provide a guideline for the non-battery experts, the cells' specs are highlighted with different colors in which the green and the yellow colors represent the best and the worst specs, respectively.

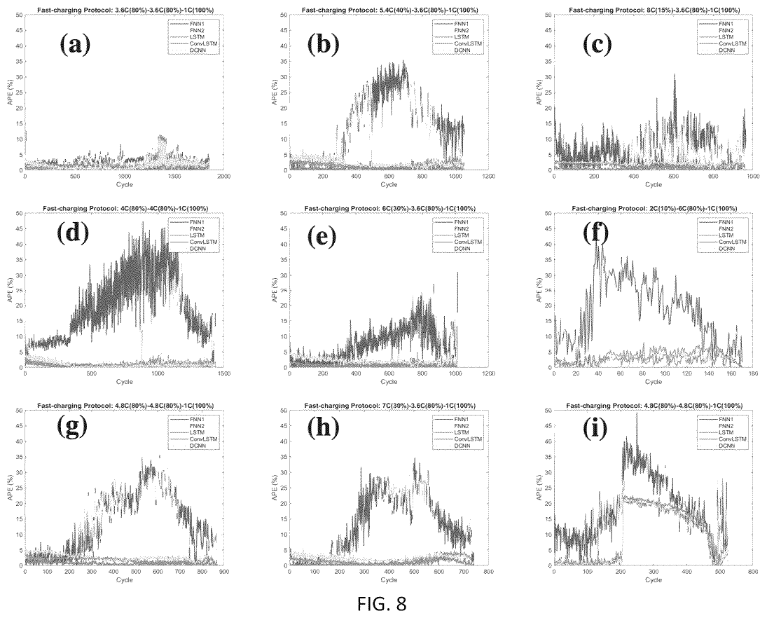

It can be seen in FIGS. 5A-C that although the voltage signals for the nine cells shows similar trends, the temperature sensor data for the cell with the charging protocol 4.8C(80%)-4.8C(80%)-1C(100%) shown in FIG. 5C with blue color deviates from the normal trends. As a result of such an anomaly, as shown in FIG. 8I, the absolute percentage error (APE) for the SOH prediction (with best models) has jumped from less than 5% to more than 20%. Such a dramatic change in the SOH may indicate a sensor error originated from malfunctions in the battery pack and therefore can indicate a potential capability for anomaly detection in the EV battery pack.

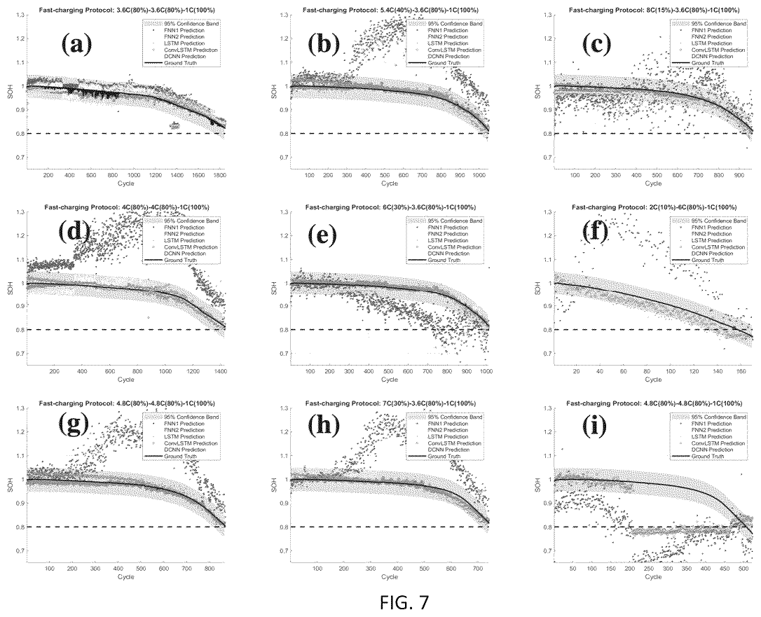

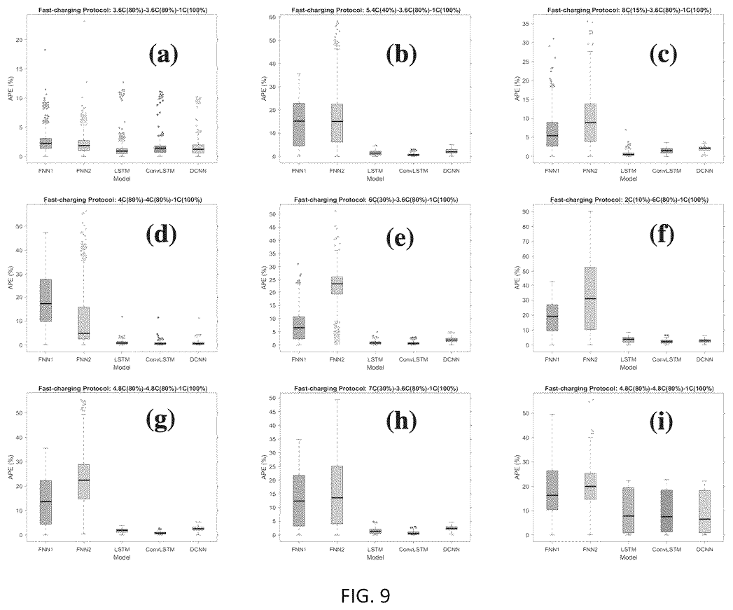

FIGS. 7A-I are charts illustrating estimated state of health (SOH) over cycle numbers with various charging protocols provided by the deep learning module 200 for the nine battery cells listed in FIG. 6. FIGS. 8A-I are charts illustrating absolute percentage error (APE) of the estimated SOH of FIG. 7A-I. FIGS. 9A-I are box plots of the APE of FIG. 8A-I.

The performance metrics may be defined based on the results obtained from the prediction ( [symbol] ) and the results obtained from the real experimental data (SOH) as the ground truth. In order to evaluate the model performance for each single testing cell, the absolute percentage error (APE) can be defined as follows:

$$APE = \vert \frac{- SOH}{SOH} \vert \times 100 \%$$

APE defines the relative error at each predicted point by the model. For instance, for the cell with 700 cycles data, the model output is a vector with size 700×1.

The mean absolute percentage error (MAPE) score of each model on each battery cell is a performance metric for different cells with varying charging protocols. MAPE can be used to evaluate the robustness of the model on the cell performance under different charging conditions. MAPE indicates the average accuracy of each model over the whole life of the battery cell from cycle 1 to cycle n. MAPE can be defined as follows:

$$MAPE = \frac{{\sum }_{i = 1}^{n} {APE}_{i}}{n}$$

The mean deviation from the MAPE (MSigma) of each model for each cell indicates the consistency of the accuracy of the model to predict the [symbol] by indicating the average deviation of the predicted [symbol] value. MSigma can be defined as follows:

$$MSigma = \frac{{\sum }_{i = 1}^{n} \vert {APE}_{i} - MAPE \vert}{n}$$

The prediction results provided by the deep learning model 200 show an unexpected SOH estimation for the battery cell charged with the charging protocol 4.8C(80%)-4.8C(80%)-1C(100%) shown in FIG. 71. Also, FIG. 8I indicates that the APE dramatically increases after cycle 200. In order to investigate the reasons for such an unexpected prediction, the raw data from the current, Voltage, and temperature sensors are tracked and shown in FIGS. 5A-5C.

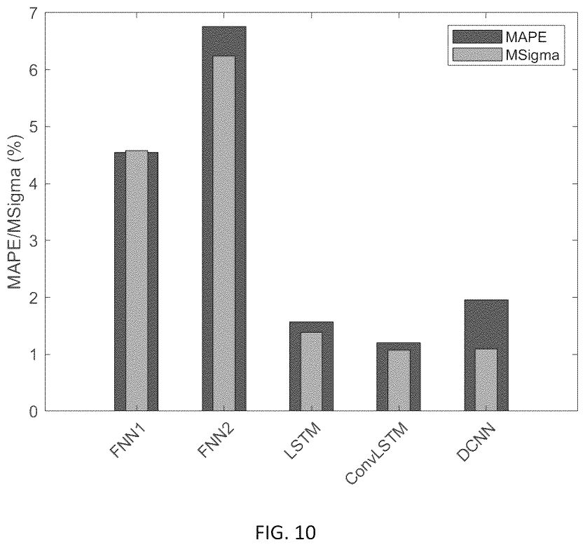

FIG. 10 is a chart comprising the mean absolute percentage error (MAPE) and the mean deviation from the MAPE (MSigma) between FNN1, FNN2, LSTM, ConvLSTM, and DCNN models implemented in the exemplary deep learning module 200. FNN1 includes one hidden layer and ten neurons. FNN2 includes four hidden layers and thirty neurons at each layer. The LTSM includes one zero masking layer, six LSTM layers with eighty nodes per layer, and three dense layers. In the ConvLSTM, 3×3 kernel size has been used to extract the feature into the model. The rest of the configurations are similar to the LSTM architecture. Regularization was employed in the network in the shape of dropout layers, utilizing a certain probability for each node to be randomly deactivated from being trained in the training step to reduce the chance of overfitting. The DCNN model has been trained using fifty epochs and a minibatch of 256 observations. The initial learning rate of 0.01 for all the convolutional layers and fully connected (FC) layers have been considered. The learning rate will be adjusted for better efficient training at each ten epochs by factor of 8. The summary of the DCNN architecture is shown in Table 1.

TABLE 1
The summary of the DCNN model architecture.

| | | Number of | Stride | Number of | Number of |
|---|---|---|---|---|---|
| Layer | Filter Size | Kernels | Size | Weights | Biases |
| Input | 100 × 3 × 1 | — | — | — | — |
| Convolution 1 | 1 × 2 × 1 | 32 | (1.1) | 64 | 32 |
| Max Pooling | 3 × 1 × 1 | 32 | (3.1) | — | — |
| Convolution 2 | 3 × 1 × 1 | 64 | (1.1) | 192 | 64 |
| Convolution 3 | 3 × 1 × 1 | 100 | (1.1) | 300 | 100 |
| Convolution 4 | 3 × 1 × 1 | 100 | (1.1) | 300 | 100 |
| FC 1 | 100 × 1 | — | — | 30000 | 100 |
| FC 2 | 100 × 1 | — | — | 10000 | 100 |
| FC 3 | 1 × 1 | — | | 100 | 1 |

It can be seen in FIGS. 8A-I and FIGS. 9A-I that LSTM, ConvLSTM and DCNN possess the lowest average APE compared to the FNN models. Between LSTM, ConvLSTM and DCNN models, the ConvLSTM shows slightly higher accuracy. In order to compare the overall performance of different models, the average values of MAPE and MSigma from different tested cells for each model is calculated and shown in FIG. 10 and Table 2. The overall performance of the studied deep learning models shows that LSTM, DCNN, and LSTM generally outperform compared to both FNN models. The LSTM model shows lower overall MAPE compared to DCNN. As a result, LSTM has provided more accurate results compared to DCNN. However, the overall MSigma value for the DCNN model is lower than that of LSTM, showing that the DCNN outperforms in terms of the consistency of the accuracy for different testing protocols.

TABLE 2
Comparison of the overall MAPE and MSigma

| Model | FNN1 | FNN2 | LSTM | ConvLSTM | DCNN |
|---|---|---|---|---|---|
| MSigma (%) | 4.58 | 6.23 | 1.38 | 1.07 | 1.10 |
| MAPE (%) | 4.54 | 6.75 | 1.57 | 1.20 | 1.96 |

The deep learning module 200 is configured to use the best algorithm to predict the SOH depends on the condition. For instance, in the results obtained from the existing data, the ConvLSTM has the best performance both from the MAPE and MSigma point of views, indicating the fact that ConvLSTM architecture possessed both the accuracy (MAPE) of the LSTM and constancy (MSigma) of DCNN. In other words, the feature extraction capability of the DCNN architecture and time memory capability of the LSTM architecture can combine toward building a highly robust architecture. Such a hybrid architecture is highly applicable in the Li-ion battery SOH estimation in EV industry.

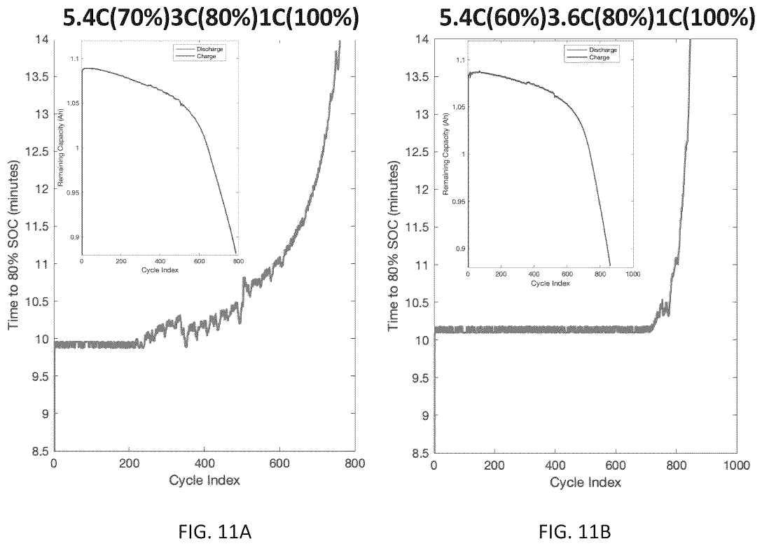

FIGS. 11A-11B show the charging time from 0% to 80% SOC versus the cycle number for two different charging protocols. It can be seen that, for the cell with the charging protocol 5.4C(70%)3C(80%)1C(100%) as shown in FIG. 11A, the charging time is highly noisy and training the model with such a feature brings considerable uncertainty into the prediction from the ML model. On the other hand, for the cell with charging protocol 5.4C(60%)3.6C(80%)1C(100%) shown in FIG. 11B, the charging time does not change with the cycle number up to cycle 700. Accordingly, it cannot provide sufficient information for the deep learning models to predict the SOH. In contrast with the conventional methods to extract features for training, the method described herein have employed the complete set of raw data during partially charged sessions of the cells as the input without the extraction or selection of characteristic features toward training different deep learning model.

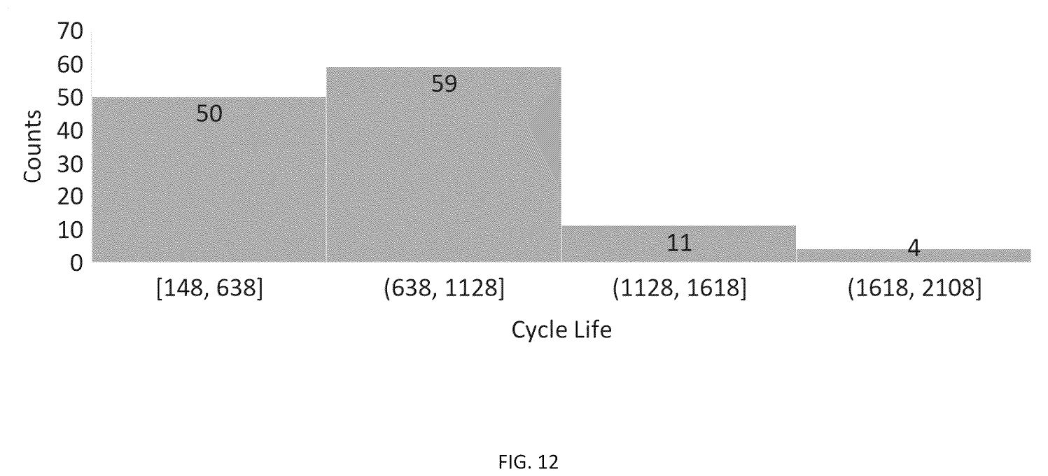

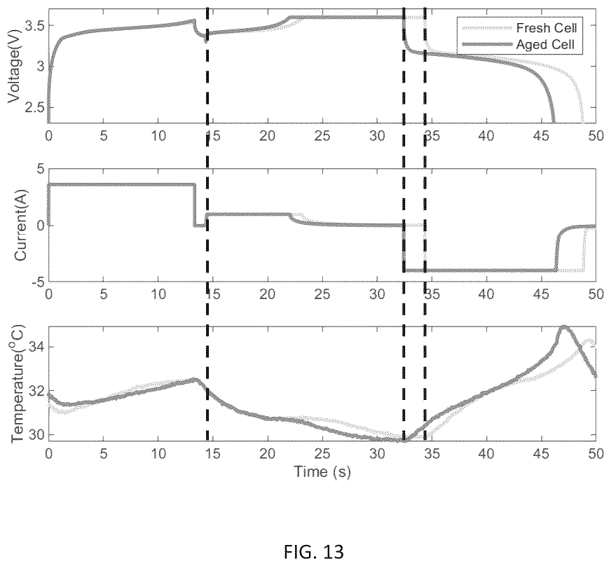

An exemplary method of training the deep learning module 200 will be discussed in connection with FIGS. 12-13. FIG. 12 is a chart showing cycle life distribution of an exemplary training dataset including 124 cells. FIG. 13 is a chart illustrating exemplary inputs into the exemplary deep learning module 200.

In the illustrated example, the deep learning module 200 have been trained and tested with a dataset including data of 124 cells. The training starts with categorizing the 124 cells into 4 groups based on the cycle life, as shown in FIG. 12. The minimum and the maximum cycle life are 148 and 1935, respectively. In order to obtain the number of the cell at each category, a constant bin width of 490 cycles has been used and the distribution of the cycle life within the 4 groups has been obtained. It can be seen that most of the cells have cycle life between 148 and 1128 cycles. Also, the average cycle life of all the cells is 774 cycles. From each group, randomly one cell has been sampled and totally 4 cell data have been used to train the model. The data sets have been made of current, voltage, and temperature time series for each cell at each cycle.

Since, in the real world, specifically in the EV application, there exist more possibilities to control the current during the cell charging than during discharging, the data during the charge session has been used to build the model. The charge session data has been used to develop the model. The I_{cut-off} and V_{cut-off} have been considered 1.001 A and 3V, respectively. The values for the I_{cut-off} and V_{cut-off} are selected such that the charge session data points from 80% state of charge (SOC) to 100% SOC are extracted correctly from the raw data.

The exemplary method uses only part of the charge session data to develop the models for the following reasons: i) in the real scenario, accessing to the full charge session from SOC 0% to SOC 100% is difficult, since the battery might never experience highly low SOC (e.g. less than 5%); ii) the optimized charging protocols can be modified with regard to the cell SOH; however, the process of slow charging at the end of the charge session is a constraint that needs to be maintained given the Li-ion battery's specification; and iii) all the charging protocols need to be followed by a constant voltage (CV) mode at the end of the charging session due to technical issues for which the explanation is out of the scope of this work.

Given the aforementioned reasons, a part of the charging session data has been used to build the model. Referring to FIG. 13, the dashed lines show the start and the end of the partially charged session. It can be seen that the end of the partially charged session has changed as the cell ages. Table shows an exemplary algorithm configured to generate the partially charged sessions based on the raw data. The partially charged sessions can be provided to the deep learning module 200 as the input data.

TABLE 3
The algorithm used to find the partially
charged session from the raw data

| | Pseudocode | Description |
|---|---|---|
| 1: | function PartialChargeData (Dataset, | |
| | I_{cut-off}, V_{cut-off}) | |
| 2: | for i = 1, 2, 3, ... 124 do | Cover all the cell |
| 3: | N ← last cycle for cell # i | Update Cycle number |
| 4: | for n = 1, 2, 3, ... , N do | Cover all the cycles |
| 5: | if I(t) > 0 &... | Find the sampling time for |
| | I(t) > I_{cut-off} & ... | each cycle |
| | V (t) > V_{cut-off}... | |
| 6: | tₛₐₘₚₗₑ ← t | Update the sampling time |
| 7: | end if | |
| 8: | I ₚ(i, n) [symbol] I (tₛₐₘₚₗₑ) | Store the partial current |
| 9: | V ₚ(i, n) [symbol] V (tₛₐₘₚₗₑ) | Store the partial voltage |
| 10: | Tₚ (i, n) [symbol] T(tₛₐₘₚₗₑ) | Store the partial temperature |
| 11: | end for | |
| 12: | end for | |
| 13: | end function | |

After obtaining the partially charged session, the current, temperature and voltage curves have been discretized to 100 sections. Then average value of each discretized section has been obtained to make the matrix where V̅ᵢ, Îᵢ, and \hat{T}ᵢ respectively represent the average of discretized values of the voltage, current, and temperature for the j^{th} segment measured at the j^{th} time interval of a partially charged session for the cycle #n.

$$Cycle Input = {[ \begin{matrix}{\overline{V}}_{1} & {\overline{I}}_{1} & {\overline{T}}_{1} \\ ⋮ & ⋮ & ⋮ \\ {\overline{V}}_{j} & {\overline{I}}_{j} & {\overline{T}}_{j} \\ ⋮ & ⋮ & ⋮ \\ {\overline{V}}_{100} & {\overline{I}}_{100} & {\overline{T}}_{100}\end{matrix} ]}_{100 \times 3}$$

In the next step, each cycle input matrix is reshaped and made a matrix with dimension 1×300. Then, all the cycle inputs are stacked to shape the input data for the partial charging session of each battery cell studied in this work. Each cycling is made of the charge session with a variety of the charging protocols followed by a discharge session with constant discharge. In this example, the cells studied in this work have been discharged with 4C discharge rate. As a result, the discharge capacity obtained from each cycle n has been used to obtain the ground truth output to train the model.

$${[ \begin{matrix}{\overline{V}}_{1} & ⋯ & {\overline{V}}_{j} & ⋯ & {\overline{V}}_{100} & {\overline{I}}_{1} & ⋯ & {\overline{I}}_{j} & ⋯ & {\overline{I}}_{100} & {T}_{1} & ⋯ & {T}_{j} & ⋯ & {T}_{100}\end{matrix} ]}_{1 \times 300} from cycle 1$$

$${[ \begin{matrix}{\overline{V}}_{1} & ⋯ & {\overline{V}}_{j} & ⋯ & {\overline{V}}_{100} & {\overline{I}}_{1} & ⋯ & {\overline{I}}_{j} & ⋯ & {\overline{I}}_{100} & {T}_{1} & ⋯ & {T}_{j} & ⋯ & {T}_{100}\end{matrix} ]}_{1 \times 300} from cycle n$$

$${[ \begin{matrix}{\overline{V}}_{1} & ⋯ & {\overline{V}}_{j} & ⋯ & {\overline{V}}_{100} & {\overline{I}}_{1} & ⋯ & {\overline{I}}_{j} & ⋯ & {\overline{I}}_{100} & {T}_{1} & ⋯ & {T}_{j} & ⋯ & {T}_{100}\end{matrix} ]}_{1 \times 300} from cycle N$$

The matrix shown in the following Eq. is the input data from cycle 1 to N used to train the model.

$${[ \begin{matrix}{\overline{V}}_{1}^{1} & ⋯ & {\overline{V}}_{j}^{1} & ⋯ & {\overline{V}}_{100}^{1} & {\overline{I}}_{1}^{1} & ⋯ & {\overline{I}}_{j}^{1} & ⋯ & {\overline{I}}_{100}^{1} & {\overline{T}}_{1}^{1} & ⋯ & {\overline{T}}_{j}^{1} & ⋯ & {\overline{T}}_{100}^{1} \\ ⋮ & ⋮ & ⋮ & ⋮ & ⋮ & ⋮ & ⋮ & ⋮ & ⋮ & ⋮ & ⋮ & ⋮ & ⋮ & ⋮ & ⋮ \\ {\overline{V}}_{1}^{N} & ⋯ & {\overline{V}}_{j}^{N} & ⋯ & {\overline{V}}_{100}^{N} & {\overline{I}}_{1}^{N} & ⋯ & {\overline{I}}_{j}^{N} & ⋯ & {\overline{I}}_{100}^{N} & {\overline{T}}_{1}^{N} & ⋯ & {\overline{I}}_{j}^{N} & ⋯ & {\overline{I}}_{100}^{N}\end{matrix} ]}_{N \times 300}$$

Each cycling is made of the charge session with a variety of the charging protocols followed by a discharge session with constant discharge. All the cells studied in this work have been discharged with 4C discharge rate. As a result, the discharge capacity obtained from each cycle n has been used to obtain the ground truth output to train the model.

$${Y}_{n} = {SOH}_{n} = ( \frac{Discharge {Capacity}_{cycle \#1}}{Discharge {Capacity}_{cycle \# n}} )$$

It should be appreciated that the discharge capacity in the data sets is directly the output from the battery cycler. However, the discharge capacity can also be calculated using the coulomb counting method, which is the time integration of the discharge current over the discharge time for the entire full discharge cycle shown in the following Eq.

$$Discharge {Capacity}_{cycle \# n} = {\int }_{T = begining of discharge}^{T = end of discharge} I ( t ) dt$$

The discharge capacity obtained from the above Eq. and the one directly obtained from the battery cycler raw data are in agreement.

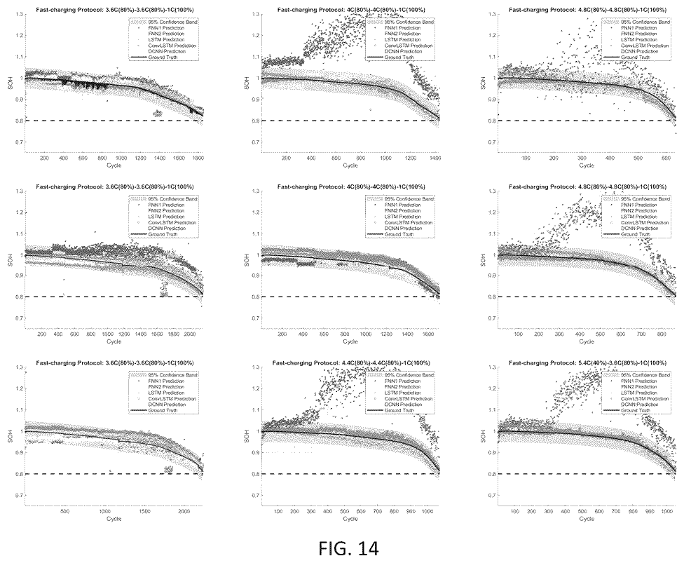

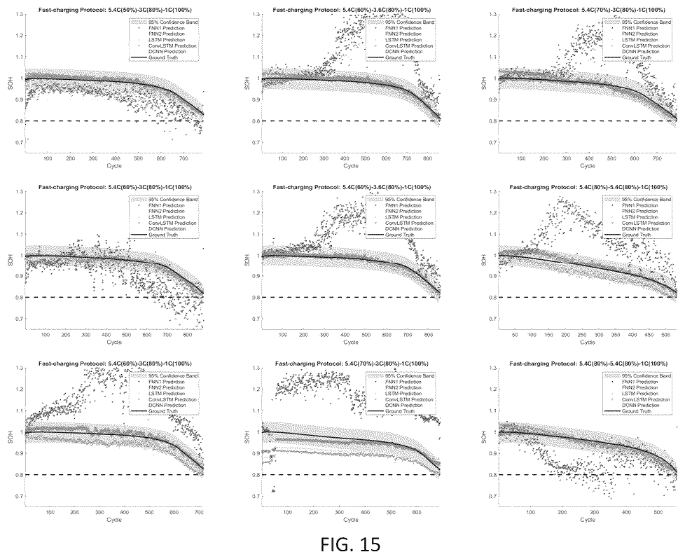

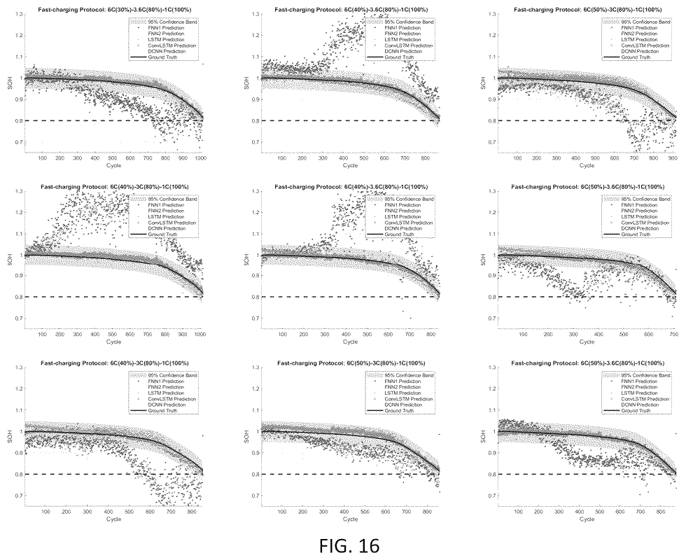

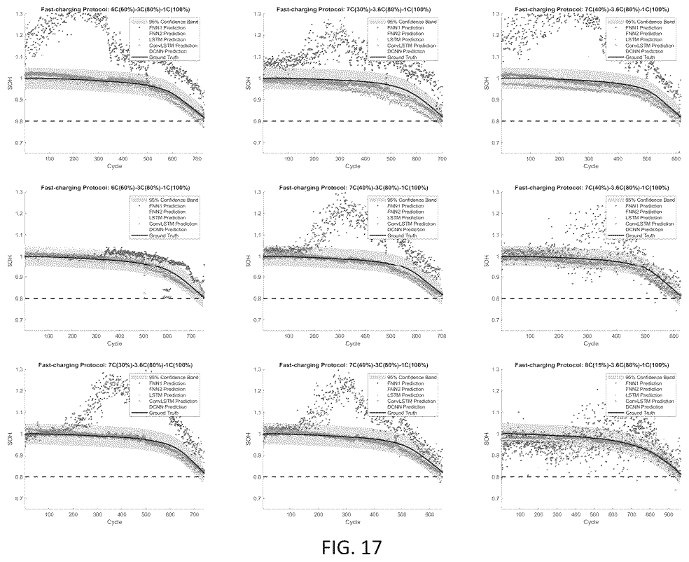

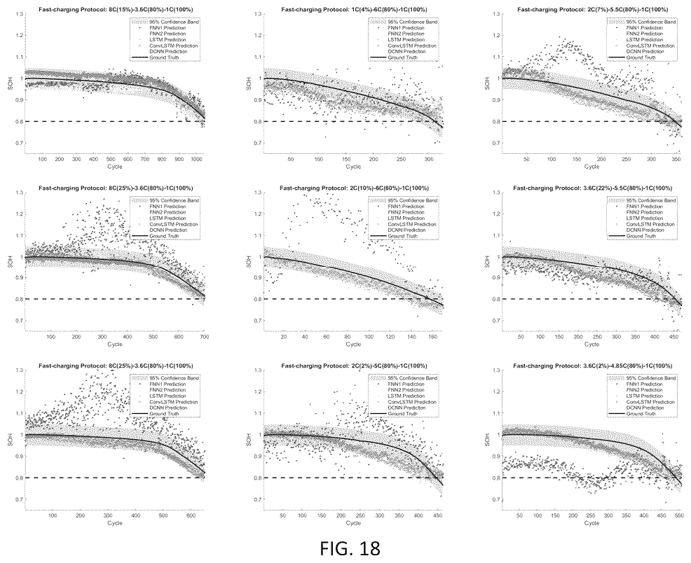

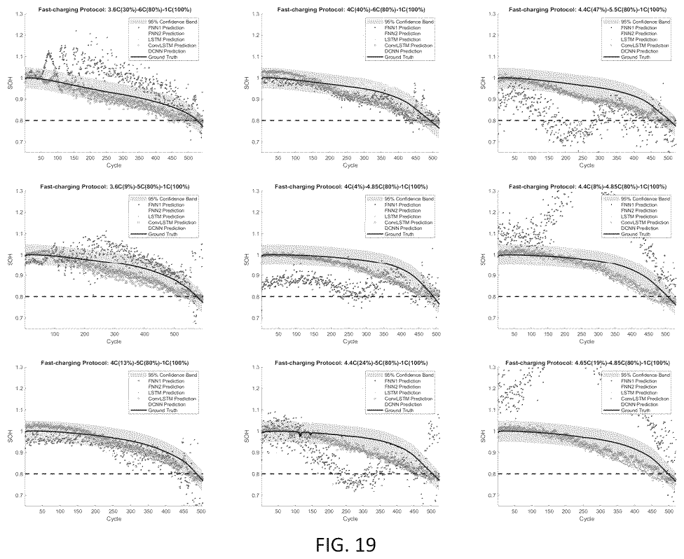

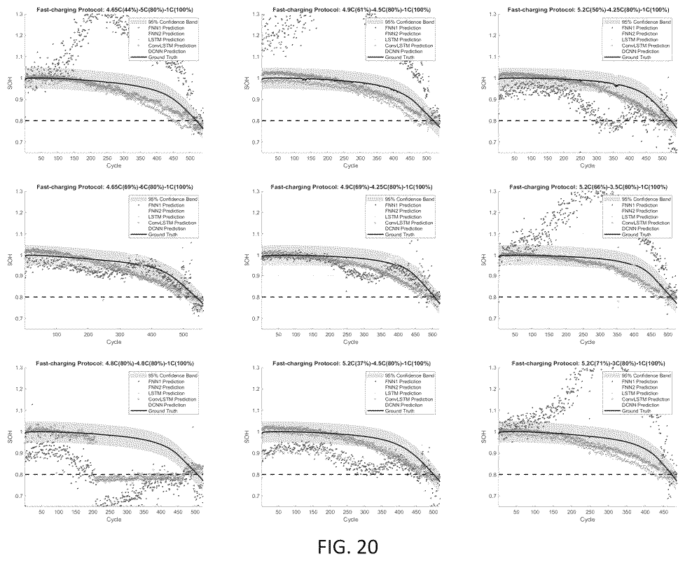

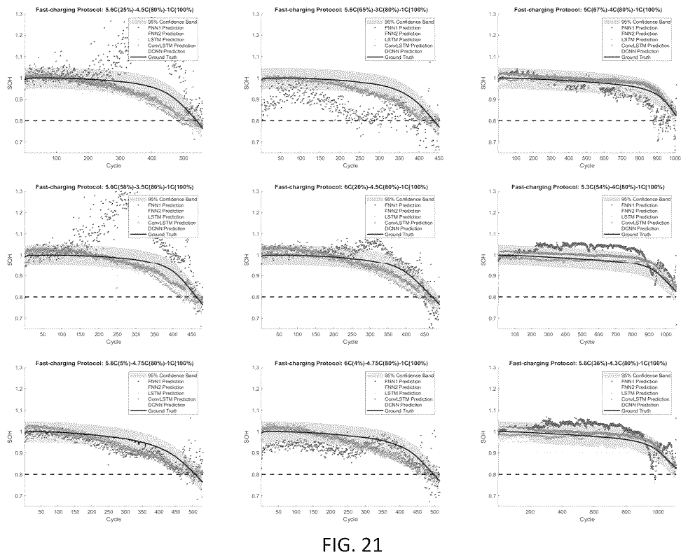

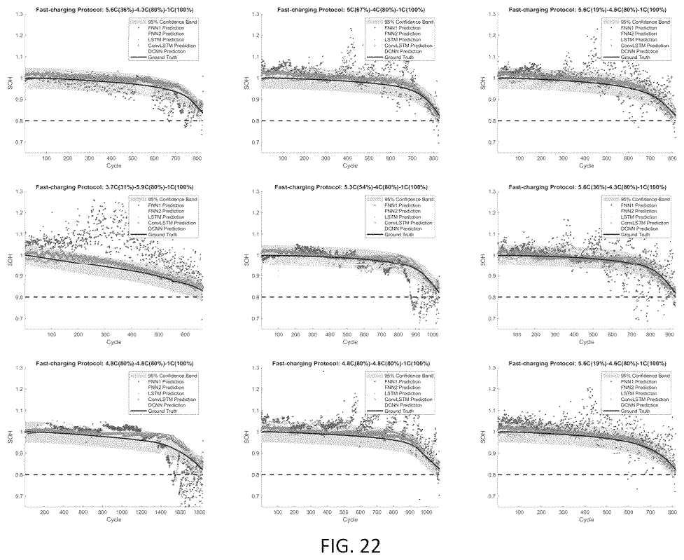

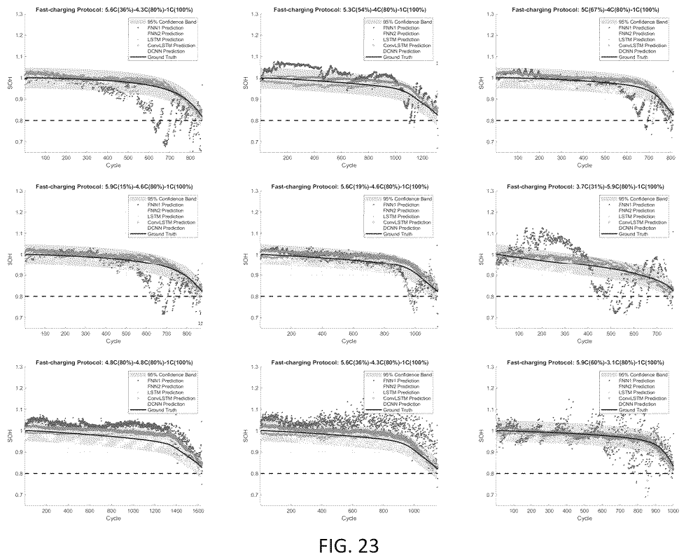

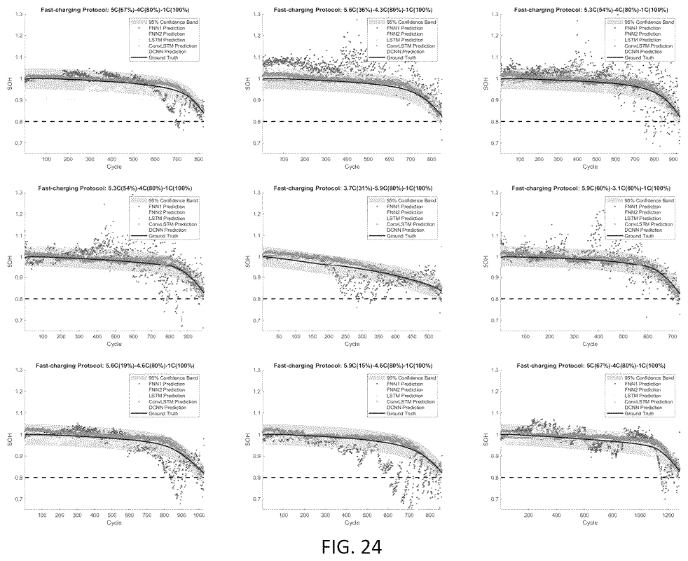

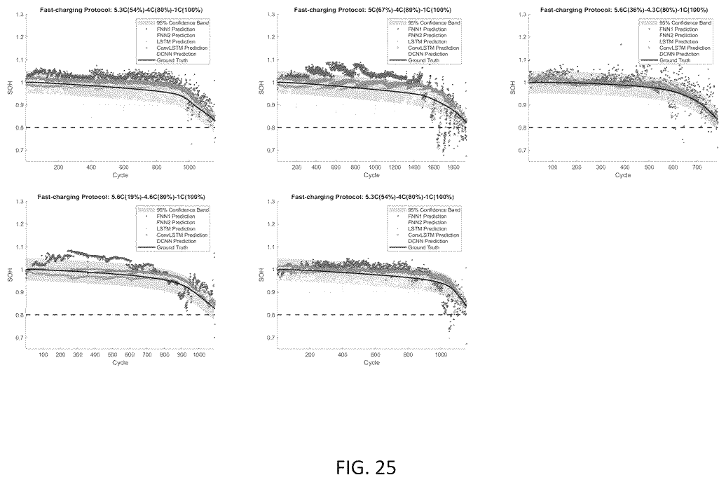

FIGS. 14-25 are charts illustrating estimated state of health (SOH) over cycle numbers with various charging protocols provided by the deep learning module 200. The charts show the prediction results for the 104 cells, which includes 4 cells from the training data and 100 cells from testing data.

Having thus described several aspects of several embodiments of a machine vision system and method of operating the machine vision system, it is to be appreciated that various alterations, modifications, and improvements will readily occur to those skilled in the art. Such alterations, modifications, and improvements are intended to be part of this disclosure, and are intended to be within the spirit and scope of the invention. While the present teachings have been described in conjunction with various embodiments and examples, it is not intended that the present teachings be limited to such embodiments or examples. On the contrary, the present teachings encompass various alternatives, modifications, and equivalents, as will be appreciated by those of skill in the art.

Further, though some advantages of the present disclosure may be indicated, it should be appreciated that not every embodiment of the disclosure will include every described advantage. Some embodiments may not implement any features described as advantageous. Accordingly, the foregoing description and drawings are by way of example only.

All literature and similar material cited in this application, including, but not limited to, patents, patent applications, articles, books, treatises, and web pages, regardless of the format of such literature and similar materials, are expressly incorporated by reference in their entirety. In the event that one or more of the incorporated literature and similar materials differs from or contradicts this application, including but not limited to defined terms, term usage, described techniques, or the like, this application controls.

Also, the technology described may be embodied as a method, of which at least one example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

In some embodiments, any suitable computer readable media can be used for storing instructions for performing the functions and/or processes described herein. For example, in some embodiments, computer readable media can be transitory or non-transitory. For example, non-transitory computer readable media can include media such as magnetic media (such as hard disks, floppy disks, etc.), optical media (such as compact discs, digital video discs, Blu-ray discs, etc.), semiconductor media (such as RAM, Flash memory, electrically programmable read only memory (EPROM), electrically erasable programmable read only memory (EEPROM), etc.), any suitable media that is not fleeting or devoid of any semblance of permanence during transmission, and/or any suitable tangible media. As another example, transitory computer readable media can include signals on networks, in wires, conductors, optical fibers, circuits, or any suitable media that is fleeting and devoid of any semblance of permanence during transmission, and/or any suitable intangible media.

It should be understood that the above-described acts of the methods described herein can be executed or performed in any order or sequence not limited to the order and sequence shown and described. Also, some of the above acts of the methods described herein can be executed or performed substantially simultaneously where appropriate or in parallel to reduce latency and processing times.

All definitions, as defined and used, should be understood to control over dictionary definitions, definitions in documents incorporated by reference, and/or ordinary meanings of the defined terms.

The indefinite articles “a” and “an,” as used in the specification and in the claims, unless clearly indicated to the contrary, should be understood to mean “at least one.”

The phrase “and/or,” as used in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively.

The claims should not be read as limited to the described order or elements unless stated to that effect. It should be understood that various changes in form and detail may be made by one of ordinary skill in the art without departing from the spirit and scope of the appended claims. All embodiments that come within the spirit and scope of the following claims and equivalents thereto are claimed.

What is claimed is:

1. A method for evaluating an energy storage system (ESS), the method comprising:
accessing, with a deep learning module, time series data of the ESS;
reshaping, with the deep learning module, the time series data of the ESS; and
generating, with the deep learning module, predicted state information about the ESS based on the reshaped data.

2. The method of claim 1, wherein:
the time series data of the ESS comprise one or more of voltage time series data, current time series data, and temperature time series data.

3. The method of claim 1, wherein reshaping, with the deep learning module, the time series data of the ESS comprises:
generating a partial session of the time series data based on a predetermined cutoff voltage and/or a predetermined cutoff current.

4. The method of claim 1, wherein generating, with the deep learning module, the predicted information about the ESS based on the reshaped data comprises:
selecting one or more deep learning models of the deep learning module; and
generating, with the selected one or more deep learning models of the deep learning module, the predicted state information about the ESS.

5. The method of claim 4, wherein:
the one or more selected deep learning models comprise one or more of deep feedforward neural network (DFFN), deep convolutional neural networks (DCNN), long short-term memory (LSTM), and convolutional LSTM (ConLSTM).

6. The method of claim 1, wherein:
the predicted state information about the ESS comprises predicted state of health (SOH) of the ESS under a plurality of charging protocols.

7. The method of claim 1, further comprising:
providing the predicted state information about the ESS for controlling the ESS so as to optimize the ESS's performance and extend the ESS's lifespan.

8. A system comprising at least one processor configured to execute computer executable instructions, wherein the computer executable instructions comprise instructions for:
accessing, with a deep learning module, time series data of an energy storage system (ESS);
reshaping, with the deep learning module, the time series data of the ESS; and
generating, with the deep learning module, predicted state information about the ESS based on the reshaped data.

9. The system of claim 8, wherein:
the time series data of the ESS comprise one or more of voltage time series data, current time series data, and temperature time series data.

10. The system of claim 8, wherein reshaping, with the deep learning module, the time series data of the ESS comprises:
generating a partial session of the time series data based on a predetermined cutoff voltage and/or a predetermined cutoff current.

11. The system of claim 8, wherein generating, with the deep learning module, the predicted information about the ESS based on the reshaped data comprises:
selecting one or more deep learning models of the deep learning module; and
generating, with the selected one or more deep learning models of the deep learning module, the predicted state information about the ESS.

12. The system of claim 11, wherein:
the one or more selected deep learning models comprise one or more of deep feedforward neural network (DFFN), deep convolutional neural networks (DCNN), long short-term memory (LSTM), and convolutional LSTM (ConLSTM).

13. The system of claim 8, wherein:
the predicted state information about the ESS comprises predicted state of health (SOH) of the ESS under a plurality of charging protocols.

14. The system of claim 8, further comprising:
providing the predicted state information about the ESS for controlling the ESS so as to optimize the ESS's performance and extend the ESS's lifespan.

15. A non-transitory computer readable medium comprising program instructions that, when executed, cause at least one processor to:
access, with a deep learning module, time series data of an energy storage system (ESS);
reshape, with the deep learning module, the time series data of the ESS; and
generate, with the deep learning module, predicted state information about the ESS based on the reshaped data.

16. The non-transitory computer readable medium of claim 15, wherein:
the time series data of the ESS comprise one or more of voltage time series data, current time series data, and temperature time series data.

17. The non-transitory computer readable medium of claim 15, wherein reshaping, with the deep learning module, the time series data of the ESS comprises:
generating a partial session of the time series data based on a predetermined cutoff voltage and/or a predetermined cutoff current.

18. The non-transitory computer readable medium of claim 15, wherein generating, with the deep learning module, the predicted information about the ESS based on the reshaped data comprises:
selecting one or more deep learning models of the deep learning module; and
generating, with the selected one or more deep learning models of the deep learning module, the predicted state information about the ESS.

19. The non-transitory computer readable medium of claim 18, wherein:
the one or more selected deep learning models comprise one or more of deep feedforward neural network (DFFN), deep convolutional neural networks (DCNN), long short-term memory (LSTM), and convolutional LSTM (ConLSTM).

20. The non-transitory computer readable medium of claim 15, wherein:
the predicted state information about the ESS comprises predicted state of health (SOH) of the ESS under a plurality of charging protocols.
